(19) United States
(12) Patent Application Publication
(10) Pub. No.: US 2024/0113225 A1
(43) Pub. Date: Apr. 4, 2024

(54) SEMICONDUCTOR DEVICE AND FABRICATING METHOD THEREOF

(71) Applicant: Taiwan Semiconductor Manufacturing Company, Ltd., Hsinchu (TW)

(72) Inventors: Wu-Wei Tsai, Taoyuan City (TW); Yan-Yi Chen, Taipei City (TW); Hai-Ching Chen, Hsinchu City (TW); Yu-Ming Lin, Hsinchu City (TW); Chung-Te Lin, Tainan City (TW)

(73) Assignee: Taiwan Semiconductor Manufacturing Company, Ltd., Hsinchu (TW)

(21) Appl. No.: 18/152,157

(22) Filed: Jan. 10, 2023

Related U.S. Application Data
(60) Provisional application No. 63/412,542, filed on Oct. 3, 2022.

(51) Int. Cl. H01L 29/786; H01L 29/08; H01L 29/66

(52) U.S. Cl. CPC H01L 29/7869; H01L 29/0847; H01L 29/66742

(57) ABSTRACT

A semiconductor device includes a gate, a semiconductor structure, a gate insulating layer, a first source/drain feature and a second source/drain feature. The gate insulating layer is located between the gate and the semiconductor structure. The semiconductor structure includes at least one first metal oxide layer, a first oxide layer, and at least one second metal oxide layer. The first oxide layer is located between the first metal oxide layer and the second metal oxide layer. The first source/drain feature and the second source/drain feature are electrically connected with the semiconductor structure.

### CROSS-REFERENCE TO RELATED APPLICATION

This application claims the priority benefit of U.S. provisional application Ser. No. 63/412,542, filed on Oct. 3, 2022. The entirety of the above-mentioned patent application is hereby incorporated by reference herein and made a part of this specification.

### BACKGROUND

The semiconductor industry has experienced a fast-paced growth. The semiconductor industry continues to improve the integration density of various electronic components (e.g., transistors, diodes, resistors, capacitors, etc.) by continual reductions in minimum feature size, which allow more components to be integrated into a given area. Thin film transistor (TFT) has the advantages of small size and thin thickness, so many semiconductor manufacturers are committed to developing technologies related to thin film transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device in accordance with some embodiments of the disclosure.

FIG. 2A to FIG. 2G are schematic cross-sectional views of various stages in a fabrication method of a semiconductor device in accordance with some embodiments of the disclosure.

FIG. 3 is a schematic cross-sectional view of a semiconductor device in accordance with some embodiments of the disclosure.

FIG. 4 is a schematic cross-sectional view of a semiconductor device in accordance with some embodiments of the disclosure.

FIG. 5 is a schematic cross-sectional view of a semiconductor device in accordance with some embodiments of the disclosure.

FIG. 6 is a schematic cross-sectional view of a semiconductor device in accordance with some embodiments of the disclosure.

FIG. 7 is a schematic cross-sectional view of a semiconductor device in accordance with some embodiments of the disclosure.

FIG. 8 is a schematic cross-sectional view of a semiconductor device in accordance with some embodiments of the disclosure.

FIG. 9 is a schematic cross-sectional view of a semiconductor device in accordance with some embodiments of the disclosure.

FIG. 10A to FIG. 10D are schematic cross-sectional views of various stages in a fabrication method of a semiconductor device in accordance with some embodiments of the disclosure.

FIG. 11 is a schematic cross-sectional view of an integrated circuit device in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following disclosure, Source/drain feature(s) may refer to a source or a drain, individually or collectively dependent upon the context. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

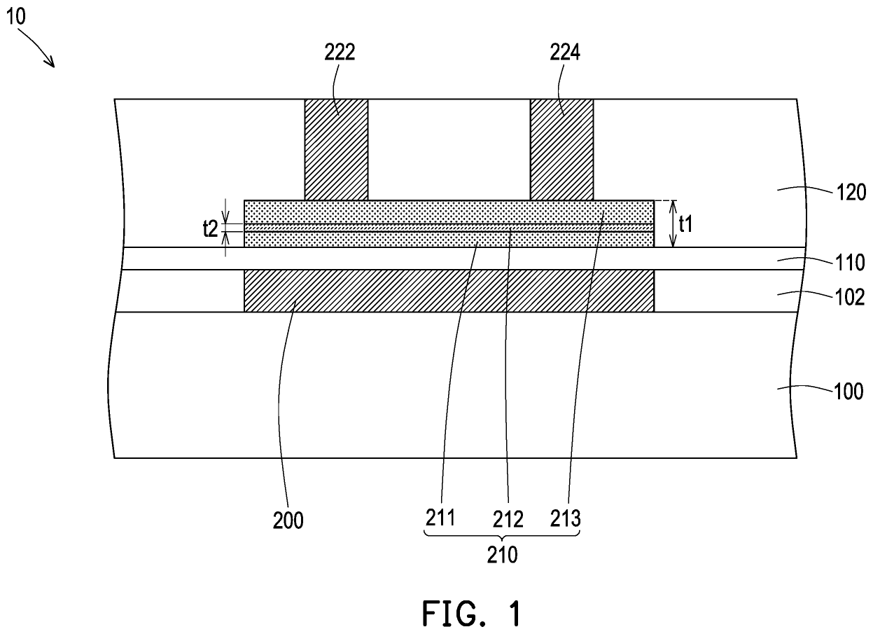

FIG. 1 is a schematic cross-sectional view of a semiconductor device 10 in accordance with some embodiments of the disclosure. Referring to FIG. 1, a semiconductor device 10 includes a gate 200, a semiconductor structure 210, a gate insulating layer 110, a first source/drain feature 222 and a second source/drain feature 224. In some embodiments, the semiconductor device 10 further includes a semiconductor substrate 100, an insulator 102 and an interlayer dielectric layer 120.

The semiconductor substrate 100 may be a silicon substrate including active components (e.g., transistors or the like) and passive components (e.g., resistors, capacitors, inductors, or the like) formed therein. The active components and passive components may be formed in the semiconductor substrate 100 through front end of line (FEOL) fabrication processes of a wafer. On the other hand, the gate 200, the semiconductor structure 210, the gate insulating layer 110, the interlayer dielectric layer 120, the first source/drain feature 222 and the second source/drain feature 224 may be formed through back end of line (B EOL) fabrication processes.

The gate 200 is disposed above the semiconductor substrate 100. In some embodiments, the insulator 102 is disposed above the semiconductor substrate 100, and the gate 200 is embedded in the insulator 102, but the disclosure is not limited thereto. In other embodiments, the insulator 102 can be omitted. The gate 200 may has a single-layer structure or a multi-layer structure. In some embodiments, the material of the gate 200 includes Mo, W, Ru, Pt, TiN, TaN, TaAlC, TiC, TaC, Co, Al, TiAl, HfTi, TiSi, TaSi or TiAlC, or a multi-layer of two or more of these materials, or other conductive material. In some embodiments, the gate 200 is electrically connected with a word line (not shown).

The gate insulating layer 110 is disposed over the gate 200 and the optionally insulator 102. In some embodiments, the gate insulating layer 110 is a multi-layer structure including an insulating layer and a ferroelectric (FE) material layer. The insulating layer in the gate insulating layer 110 may include silicon oxide (SiOx), aluminium oxide (AlOx), hafnium oxide (HfOx): zirconium oxide (ZrOx), HfOx: AlOx; HfOx: lanthanum oxide (LaOx), HfOx: SiOx, HfOx: strontium oxide (SrO), hafnium zirconium oxide (HZO) doped cerium oxide (CeOx), polymer or other suitable materials.

The semiconductor structure 210 is disposed over the gate insulating layer 110 and is overlapping with the gate 200. The gate insulating layer 110 is located between the gate 200 and the semiconductor structure 210. The semiconductor structure 210 includes a first metal oxide semiconductor 211, a first oxide layer 212 and a second metal oxide semiconductor 213. The first oxide layer 212 is located between the first metal oxide semiconductor 211 and the second metal oxide semiconductor 213. In some embodiments, the first metal oxide semiconductor 211 is consist of at least one first metal oxide layer, and the second metal oxide semiconductor 213 is consist of at least one second metal oxide layer.

In general, additional defects (e.g., oxygen vacancies) may occur in metal oxide semiconductors due to thermal processes or prolonged operations. These defects can affect the properties of metal oxide semiconductors, resulting in reduced performance of the transistor. In some embodiments, the first oxide layer 212 can inhibit the formation of additional defects (e.g., oxygen vacancies) in the first metal oxide semiconductor 211 and the second metal oxide semiconductor 213. Therefore, performance degradation of the semiconductor device 10 due to increased defect concentration in the first metal oxide semiconductor 211 and the second metal oxide semiconductor 213 can be avoided. In some embodiments, in terms of bond energy, the average bond energy between oxygen and other ions in the first oxide layer 212 is greater than the average bond energy between oxygen and other ions in the first metal oxide semiconductor 211 and the average bond energy between oxygen and other ions in the second metal oxide semiconductor 213. The dissociation energy of A-O is larger than the dissociation energy of B-O, wherein A is an atom other than oxygen in the first oxide layer 212, and B is an atom other than oxygen in the first metal oxide semiconductor 211 and the second metal oxide semiconductor 213. In other word, oxygen in the first oxide layer 212 is more stable than oxygen in the first metal oxide semiconductor 211 and oxygen in the second metal oxide semiconductor 213.

In some embodiments, the material of the first oxide layer 212 includes hafnium oxide (HfOx), zirconium oxide (ZrOx), lanthanum oxide (LaOx), silicon oxide (SiOx), aluminium oxide (AlOx), gallium oxide (GaOx), tungsten oxide (WOx) or the like. In some embodiments, the material of the first metal oxide semiconductor 211 and the material of the second metal oxide semiconductor 213 includes at least one of indium zinc oxide (IZO), indium gallium oxide (IGO), indium gallium zinc oxide (IGZO), indium tungsten oxide (IWO) or indium tungsten zinc oxide (IWZO). In some embodiments, the thickness t1 of the semiconductor structure 210 is in a range between 1 nm to 50 nm, and the thickness t2 of the first oxide layer 212 is in a range between 1 Å to 10 Å. In some embodiments, a width of the first oxide layer 212 is substantially equal to a width of the first metal oxide semiconductor 211 and a width of the second metal oxide semiconductor 213. In some embodiments, the first oxide layer 212 is a continuous film, but the disclosure is not limited thereto. In other embodiments, the first oxide layer 212 is a porous film or a discontinuous film.

An interlayer dielectric layer 120 is disposed over the gate insulating layer 110 and covers the semiconductor structure 210. In some embodiments, the material of the interlayer dielectric layer 120 may include SiOx, AlOx, HfOx:ZrOx, HfOx:AlOx; HfOx:LaOx, HfOx:SiOx, HfOx:SrO, HZO doped CeOx or other suitable materials.

A first source/drain feature 222 and a second source/drain feature 224 are disposed in openings of the interlayer dielectric layer 120 and electrically connected with the semiconductor structure 210. In other word, the first source/drain feature 222 and the second source/drain feature 224 are embedded in the interlayer dielectric layer 120 to connect the semiconductor structure 210. In some embodiments, the first source/drain feature 222 and the second source/drain feature 224 are metals or other suitable conductive materials. In some embodiments, the contact between the first source/drain feature 222 and the semiconductor structure 210 and the contact between the second source/drain feature 224 and the semiconductor structure 210 may include Schottky contact, Ohmic contact or the combination thereof.

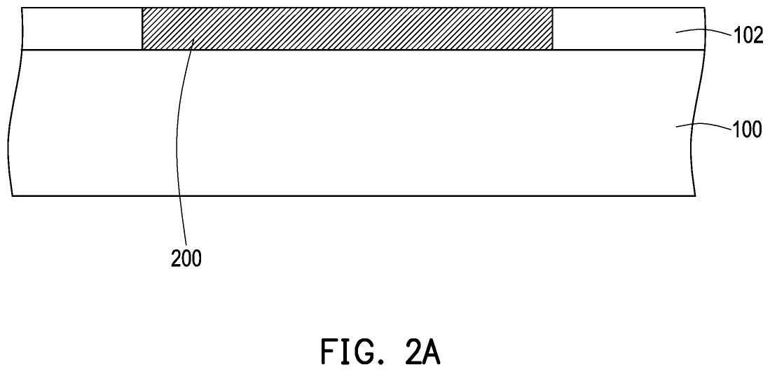

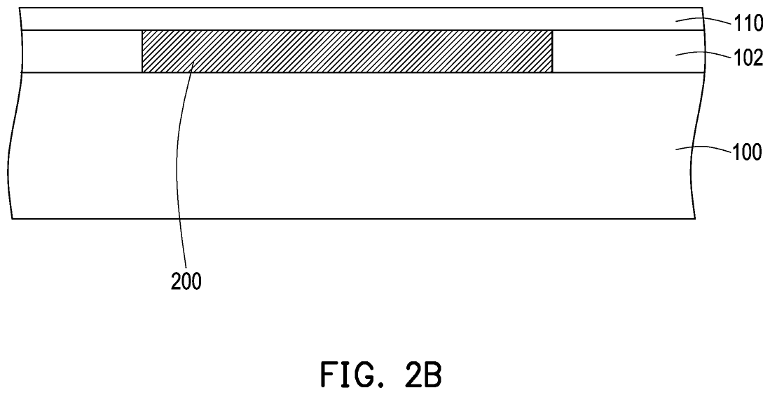

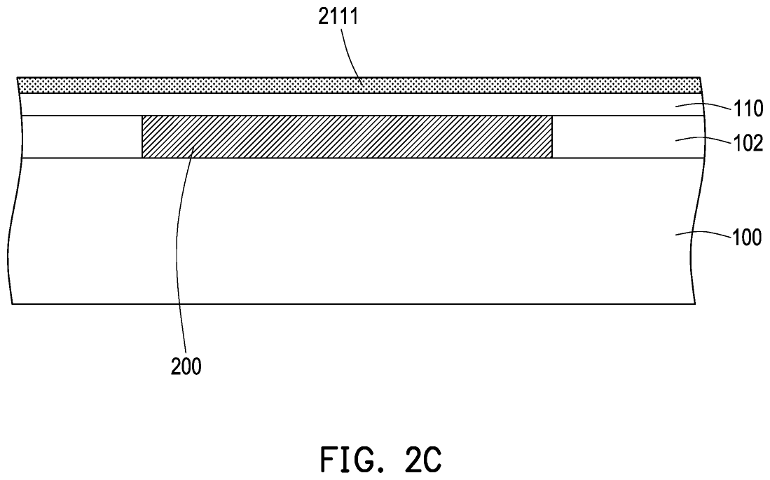

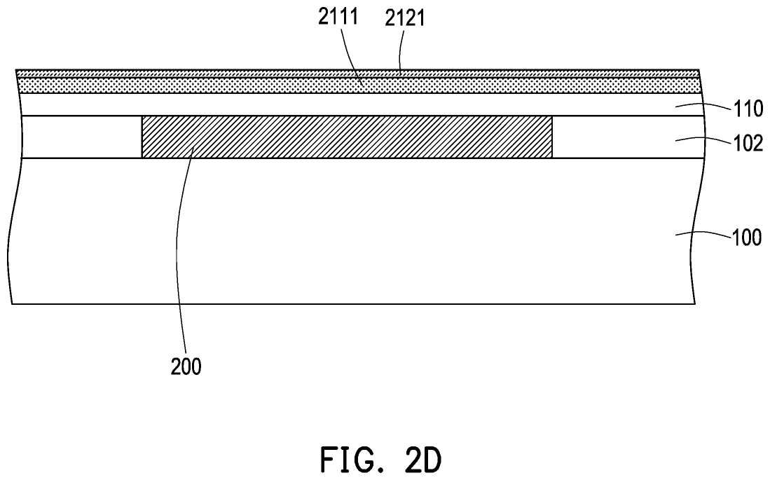

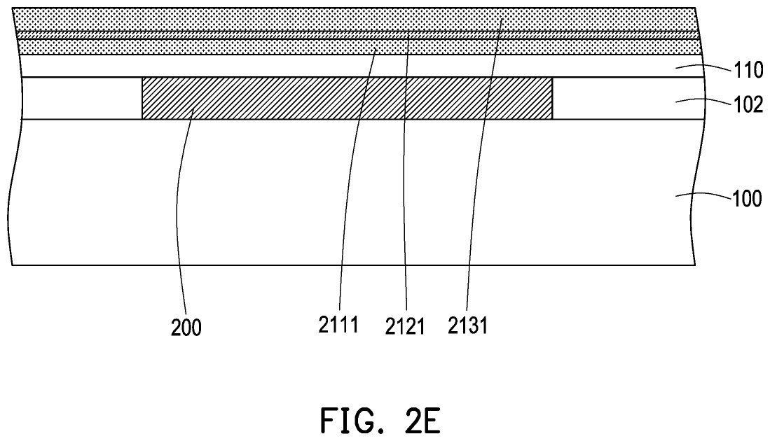

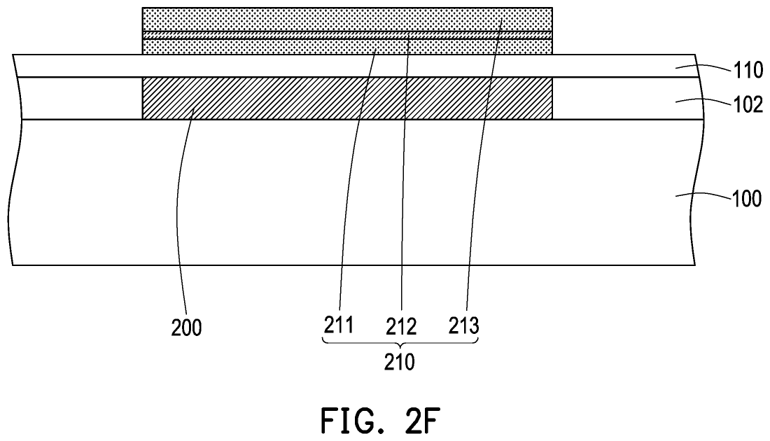

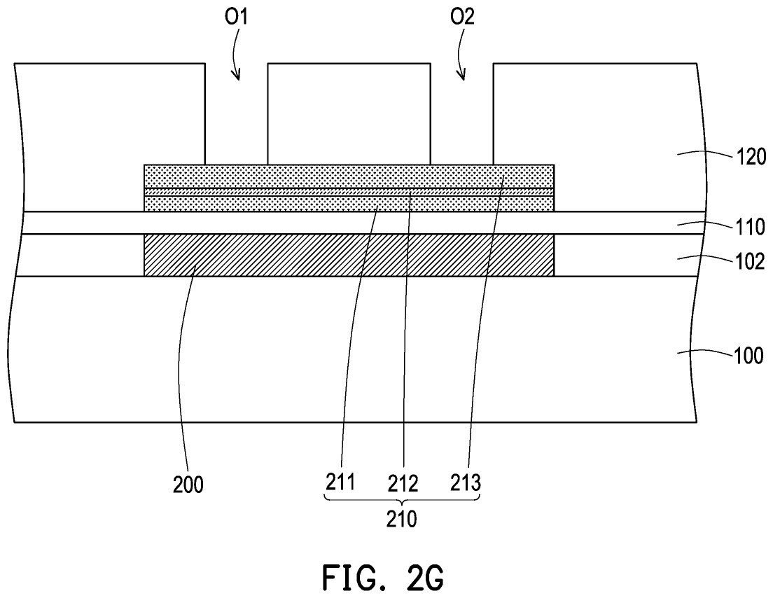

FIG. 2A to FIG. 2G are schematic cross-sectional views of various stages in a fabrication method of a semiconductor device 10 in accordance with some embodiments of the disclosure.

Referring to FIG. 2A, the gate 200 and the insulator 102 are formed above the semiconductor substrate 100. For example, a through hole is formed in the insulator 102. A method of forming the through hole includes photolithography process, etching process, or other suitable process, or the combination thereof. The gate 120 is formed in the through hole of the insulator 102. In some embodiments, one or more conductive materials are deposited, by electroplating, electroless plating, or the like, on the top surface of the insulator 102 and filling in the through hole of the insulator 102. Then, a planarization operation, such as chemical mechanical polishing (CMP) or an etch-back process, is performed so as to remove an upper part of the conductive materials to obtain the gate 200. In this embodiment, the insulator 102 is formed before forming the gate 200. However, the disclosure is not limited thereto. In other embodiments, the gate 200 is formed before forming the insulator 102.

Referring to FIG. 2B, the gate insulating layer 110 is formed over the insulator 102 and the gate 200. In some embodiments, the gate insulating layer 110 is formed by spin-on coating, atomic layer deposition (ALD), chemical vapor deposition (CVD), plasma-enhanced chemical vapor deposition (PECVD), physical vapor deposition (PVD), or the like. In some embodiments, an intermediate conductive layer (not shown) is formed on the gate 200 before forming the gate insulating layer 110. The intermediate conductive layer is one or more layers of conductive material, such as TiN, Ti, TaN and/or W.

Referring to FIG. 2C, a first metal oxide semiconductor material 2111 is formed above the gate insulating layer 110. The first metal oxide semiconductor material 2111 may include indium zinc oxide (IZO), indium gallium oxide (IGO), indium gallium zinc oxide (IGZO), indium tungsten oxide (IWO) or indium tungsten zinc oxide (IWZO). The first metal oxide semiconductor material 2111 is formed by ALD, PVD, or the like. In some embodiments, the first metal oxide semiconductor material 2111 is a multi-layer structure including first metal oxide material layers. For example, the first metal oxide semiconductor material 2111 is an indium zinc oxide semiconductor including an indium oxide layer and a zinc oxide layer. In some embodiments, the first metal oxide semiconductor material 2111 is an indium gallium oxide semiconductor including an indium oxide layer and a gallium oxide layer. In other embodiments, the first metal oxide semiconductor material 2111 may be selected from one or more of the followings: an indium oxide layer, a zinc oxide layer, a tungsten oxide layer and a gallium oxide layer.

Referring to FIG. 2D, a first oxide material layer 2121 is formed, by ALD, PVD, or the like, above the first metal oxide semiconductor material 2111.

Referring to FIG. 2E, a second metal oxide semiconductor material 2131 is formed above the first oxide material layer 2121. The second metal oxide semiconductor material 2131 may include indium zinc oxide (IZO), indium gallium oxide (IGO), indium gallium zinc oxide (IGZO), indium tungsten oxide (IWO) or indium tungsten zinc oxide (IWZO). The second metal oxide semiconductor material 2131 is formed by ALD, PVD, or the like. In some embodiments, the second metal oxide semiconductor material 2131 is a multi-layer structure including second metal oxide material layers. For example, the second metal oxide semiconductor material 2131 is an indium zinc oxide semiconductor including an indium oxide layer and a zinc oxide layer. In some embodiments, the second metal oxide semiconductor material 2131 is an indium gallium oxide semiconductor including an indium oxide layer and a gallium oxide layer. In other embodiments, the second metal oxide semiconductor material 2131 may be selected from one or more of the followings: an indium oxide layer, a zinc oxide layer, a tungsten oxide layer and a gallium oxide layer.

Referring to FIG. 2F, one or more etching process is performed to pattern the first metal oxide semiconductor material 2111, the first oxide material layer 2121 and the second metal oxide semiconductor material 2131 to form the semiconductor structure 210 including the first metal oxide semiconductor 211, the first oxide layer 212 and the second metal oxide semiconductor 213. In some embodiments, the first metal oxide semiconductor 211 includes at least one first metal oxide layer, and the second metal oxide semiconductor 213 includes at least one second metal oxide layer.

Referring to FIG. 2G, the interlayer dielectric layer 120 is formed on the semiconductor structure 210 by spin-on coating, chemical vapor deposition (CVD), plasma-enhanced chemical vapor deposition (PECVD), physical vapor deposition (PVD), or the like. A removal process is performed to forming a first opening O1 and a second opening O2 in the interlayer dielectric layer 120. In some embodiments, the removal process may include, for example, a photolithography process and an etching process. In some embodiments, the first opening O1 and the second opening O2 are stop at the upper surface of the semiconductor structure 210, but the disclosure is not limited thereto. In other embodiments, the first opening O1 and the second opening O2 are extending into the semiconductor structure 210.

Then, referring to FIG. 1, the first source/drain feature 222 and the second source/drain feature 224 are formed in the openings O1, O2 by single-damascene processes, dual-damascene processes, electroplating process or the like.

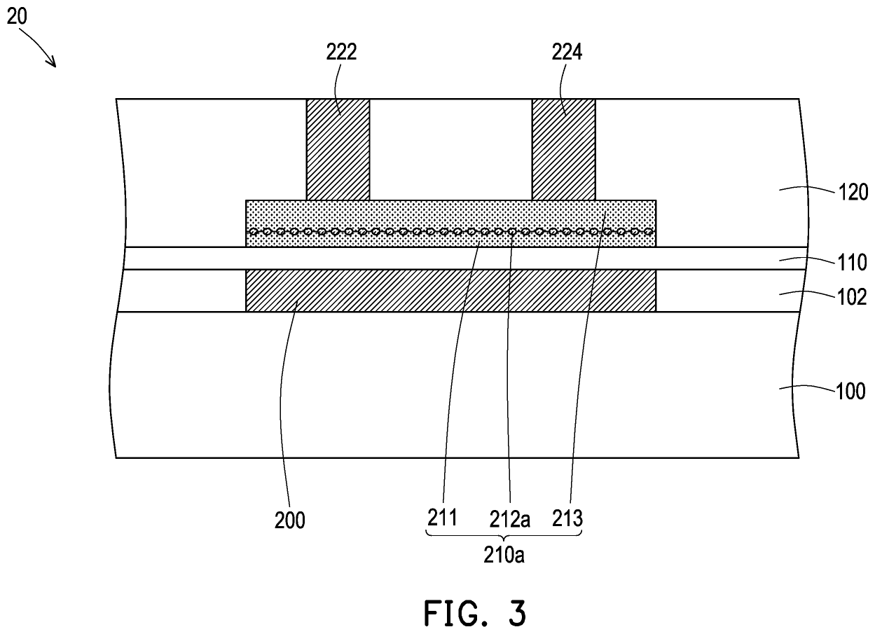

FIG. 3 is a schematic cross-sectional view of a semiconductor device 20 in accordance with some embodiments of the disclosure. It should be noted herein that, in embodiments provided in FIG. 3, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 3, a semiconductor device 20 includes a semiconductor substrate 100, an insulator 102, a gate 200, a semiconductor structure 210a, a gate insulating layer 110, an interlayer dielectric layer 120, a first source/drain feature 222 and a second source/drain feature 224. The semiconductor structure 210a includes a first metal oxide semiconductor 211, a first oxide layer 212a and a second metal oxide semiconductor 213. The first oxide layer 212a is located between the first metal oxide semiconductor 211 and the second metal oxide semiconductor 213.

In some embodiments, the average bond energy between oxygen and other ions in the first oxide layer 212a is greater than the average bond energy between oxygen and other ions in the first metal oxide semiconductor 211 and the average bond energy between oxygen and other ions in the second metal oxide semiconductor 213. The dissociation energy of A-O is larger than the dissociation energy of B-O, wherein A is an atom other than oxygen in the first oxide layer 212a, and B is an atom other than oxygen in the first metal oxide semiconductor 211 and the second metal oxide semiconductor 213. In other word, oxygen in the first oxide layer 212a is more stable than oxygen in the first metal oxide semiconductor 211 and oxygen in the second metal oxide semiconductor 213.

In some embodiments, the material of the first oxide layer 212a includes hafnium oxide (HfOx), zirconium oxide (ZrOx), lanthanum oxide (LaOx), silicon oxide (SiOx), aluminium oxide (AlOx), gallium oxide (GaOx), tungsten oxide (WOx) or the like. In some embodiments, the first oxide layer 212a includes a plurality of particles dispersed on the interface between the first metal oxide semiconductor 211 and the second metal oxide semiconductor 213.

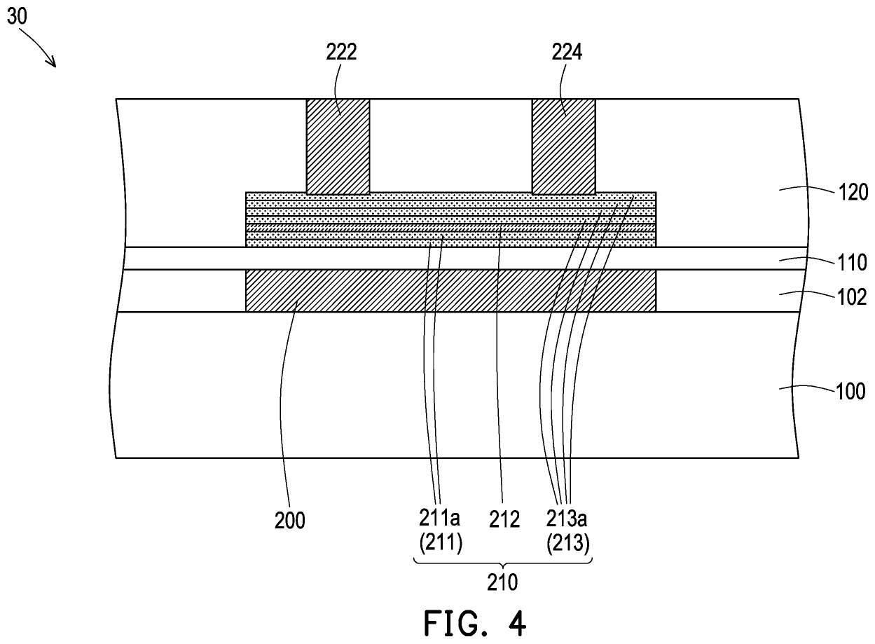

FIG. 4 is a schematic cross-sectional view of a semiconductor device 30 in accordance with some embodiments of the disclosure. It should be noted herein that, in embodiments provided in FIG. 4, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 4, the first metal oxide semiconductor 211 includes first metal oxide layers 211a, and the second metal oxide semiconductor 213 includes second metal oxide layers 213a. In some embodiments, a width of the first oxide layer 212 is substantially equal to a width of the first metal oxide layers 211a and a width of the second metal oxide layers 213a.

In some embodiments, the average bond energy between oxygen and other ions in the first oxide layer 212 is greater than the average bond energy between oxygen and other ions in the first metal oxide layers 211a and the average bond energy between oxygen and other ions in the second metal oxide layers 213a. Therefore, oxygen in the first oxide layer 212 is more stable than oxygen in the first metal oxide semiconductor 211 and oxygen in the second metal oxide semiconductor 213.

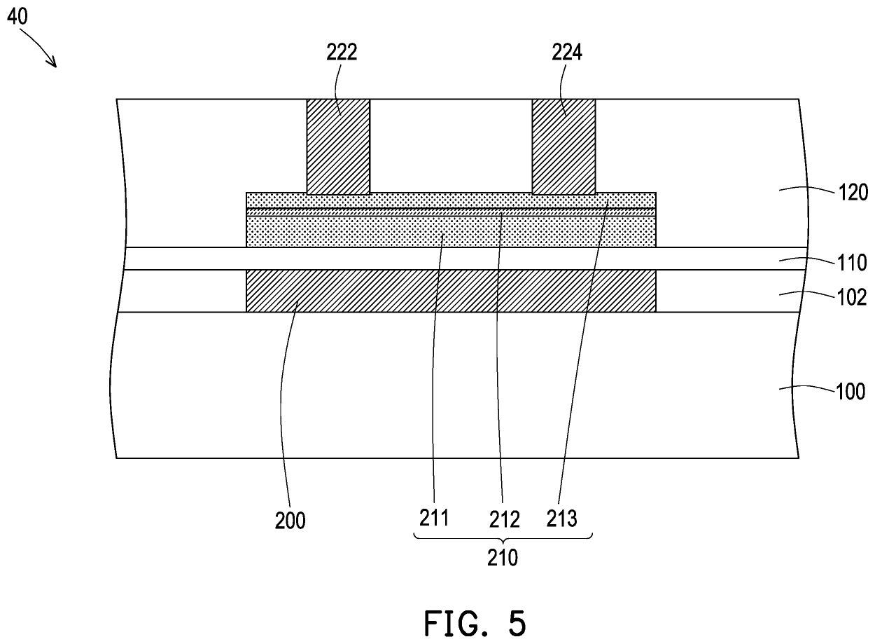

FIG. 5 is a schematic cross-sectional view of a semiconductor device 40 in accordance with some embodiments of the disclosure. It should be noted herein that, in embodiments provided in FIG. 5, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

The difference between the semiconductor device 40 in FIG. 5 and the semiconductor device 10 in FIG. 1 is that: the first oxide layer 212 is closer to the upper surface of the semiconductor structure 210 in the semiconductor device 40, and the first oxide layer 212 is closer to the lower surface of the semiconductor structure 210 in the semiconductor device 10.

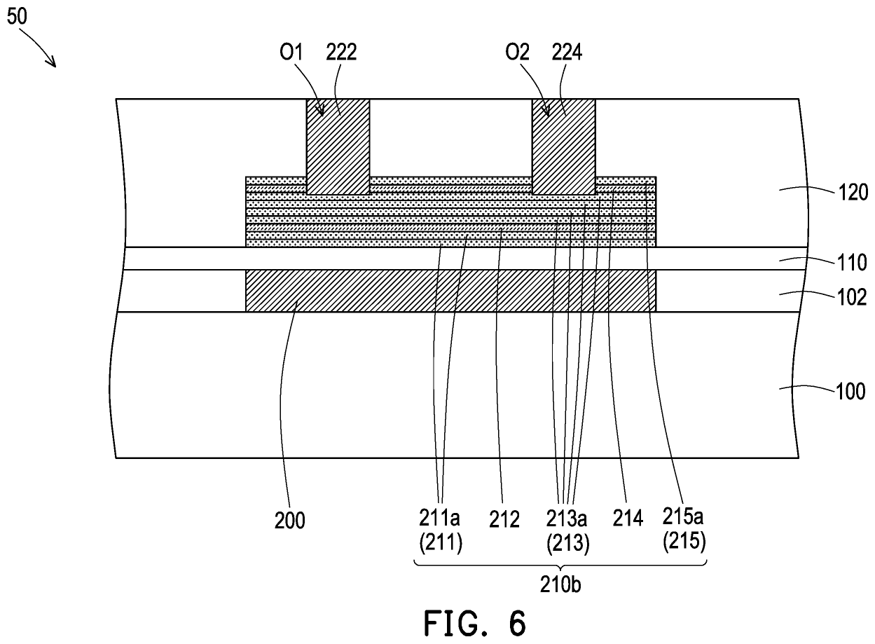

FIG. 6 is a schematic cross-sectional view of a semiconductor device 50 in accordance with some embodiments of the disclosure. It should be noted herein that, in embodiments provided in FIG. 6, element numerals and partial content of the embodiments provided in FIG. 4 are followed, the same or similar reference numerals being used to represent the same or similar elements, and description of the same technical content being omitted. For a description of an omitted part, reference may be made to the foregoing embodiment, and the descriptions thereof are omitted herein.

The difference between the semiconductor device 50 in FIG. 6 and the semiconductor device 30 in FIG. 4 is that: the semiconductor structure 210b of the semiconductor device 50 further includes a second oxide layer 214 and a third metal oxide semiconductor 215. The second oxide layer 214 is located between the second metal oxide semiconductor 213 and the third metal oxide semiconductor 215.

The third metal oxide semiconductor 215 includes at least one third metal oxide layer 215a. In some embodiments, the average bond energy between oxygen and other ions in the first oxide layer 212 and the average bond energy between oxygen and other ions in the second oxide layer 214 are greater than the average bond energy between oxygen and other ions in the first metal oxide layers 211a, the average bond energy between oxygen and other ions in the second metal oxide layers 213a and the average bond energy between oxygen and other ions in the third metal oxide layer 215a. Therefore, oxygen in the first oxide layer 212 and the second oxide layer 214 are more stable than oxygen in the first metal oxide semiconductor 211, the second metal oxide semiconductor 213 and the third metal oxide semiconductor 215.

In some embodiments, the materials of first oxide layer 212 and the second oxide layer 214 may be selected from at least one of the followings: hafnium oxide (HfOx), zirconium oxide (ZrOx), lanthanum oxide (LaOx), silicon oxide (SiOx), aluminium oxide (AlOx), gallium oxide (GaOx), tungsten oxide (WOx) and the like. In some embodiments, the materials of the first metal oxide layers 211a, the second metal oxide layers 213a and the third metal oxide layer 215a may be selected from at least one of the followings: indium oxide, zinc oxide, tungsten oxide and a gallium oxide.

In this embodiment, first metal oxide material layers, a first oxide material layer, second metal oxide material layers, a second oxide material layer and a third metal oxide material layer are formed sequentially. Then, one or more etching process is performed to pattern the first metal oxide material layers, the first oxide material layer, the second metal oxide material layers, the second oxide material layer and the third metal oxide material layer to form the first metal oxide layers 211a, the first oxide layer 212, the second metal oxide layers 213a, the second oxide layer 214 and the third metal oxide layer 215a.

In this embodiment, the first opening O1 and the second opening O2 are formed in the interlayer dielectric layer 120 by an etching process. The etching process may be an over-etching process. Therefore, the first opening O1 and the second opening O2 are extending into the semiconductor structure 210. In some embodiments, the first opening O1 and the second opening O2 penetrate through the second oxide layer 214 and the third metal oxide layer 215a. The first source/drain feature 222 and the second source/drain feature 224 are disposed in the first opening O1 and the second opening O2 and extending into the semiconductor structure 210. In some embodiments, the first source/drain feature 222 and the second source/drain feature 224 are directly in contact with the second metal oxide semiconductor 213, the second oxide layer 214 and the third metal oxide semiconductor 215.

In some embodiments, each of the first oxide layer 212 and the second oxide layer 214 is a continuous film, a porous film or a discontinuous film, but the disclosure is not limited thereto. In other embodiments, the first oxide layer 212 includes a plurality of particles dispersed on the interface between the first metal oxide semiconductor 211 and the second metal oxide semiconductor 213, and the second oxide layer 214 includes a plurality of particles dispersed on the interface between the second metal oxide semiconductor 213 and the third metal oxide semiconductor 215.

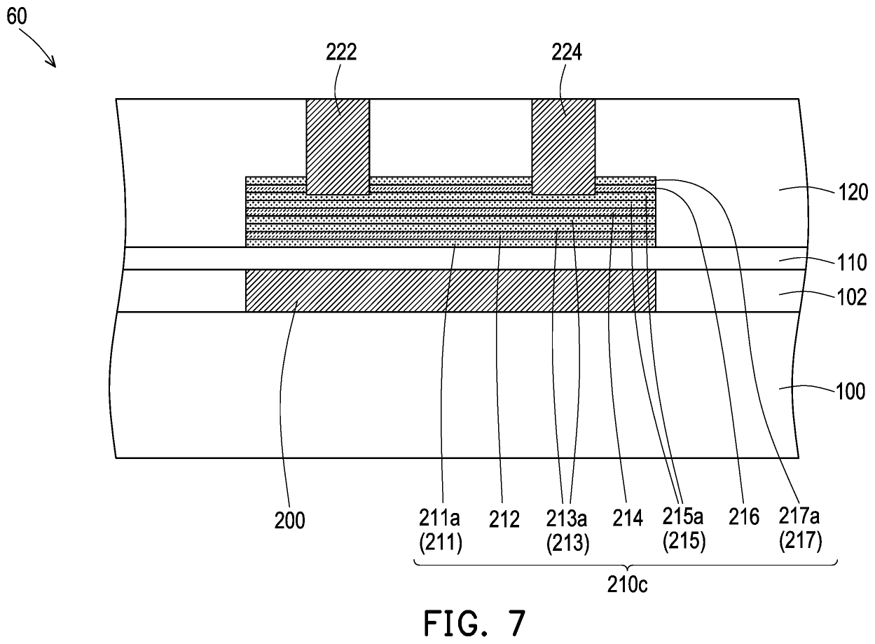

FIG. 7 is a schematic cross-sectional view of a semiconductor device 60 in accordance with some embodiments of the disclosure. It should be noted herein that, in embodiments provided in FIG. 7, element numerals and partial content of the embodiments provided in FIG. 6 are followed, the same or similar reference numerals being used to represent the same or similar elements, and description of the same technical content being omitted. For a description of an omitted part, reference may be made to the foregoing embodiment, and the descriptions thereof are omitted herein.

The difference between the semiconductor device 60 in FIG. 7 and the semiconductor device 50 in FIG. 6 is that: the semiconductor structure 210c of the semiconductor device 50 further includes a third oxide layer 216 and a fourth metal oxide semiconductor 217. The third oxide layer 216 is located between the third metal oxide semiconductor 215 and the fourth metal oxide semiconductor 217.

The fourth metal oxide semiconductor 217 includes at least one fourth metal oxide layer 217a. In some embodiments, the average bond energy between oxygen and other ions in the first oxide layer 212, the average bond energy between oxygen and other ions in the second oxide layer 214 and the average bond energy between oxygen and other ions in the third oxide layer 216 are greater than the average bond energy between oxygen and other ions in the first metal oxide layer 211a, the average bond energy between oxygen and other ions in the second metal oxide layers 213a, the average bond energy between oxygen and other ions in the third metal oxide layers 215a and the average bond energy between oxygen and other ions in the fourth metal oxide layer 217a. Therefore, oxygen in the first oxide layer 212, the second oxide layer 214 and the third oxide layer 216 are more stable than oxygen in the first metal oxide semiconductor 211, the second metal oxide semiconductor 213, the third metal oxide semiconductor 215 and the fourth metal oxide semiconductor 217.

In some embodiments, the materials of first oxide layer 212, the second oxide layer 214 and the third oxide layer 216 may be selected from at least one of the followings: hafnium oxide (HfOx), zirconium oxide (ZrOx), lanthanum oxide (LaOx), silicon oxide (SiOx), aluminium oxide (AlOx), gallium oxide (GaOx), tungsten oxide (WOx) and the like. In some embodiments, the materials of the first metal oxide layer 211a, the second metal oxide layers 213a, the third metal oxide layers 215a and the fourth metal oxide layer 217a may be selected from at least one of the followings: indium oxide, zinc oxide, tungsten oxide and a gallium oxide.

In this embodiment, a first metal oxide material layer, a first oxide material layer, second metal oxide material layers, a second oxide material layer, third metal oxide material layers, a third oxide material layer and second metal oxide material layer are formed sequentially. Then, one or more etching process is performed to pattern the first metal oxide material layer, the first oxide material layer, the second metal oxide material layers, the second oxide material layer, the third metal oxide material layers, the third oxide material layer and the fourth metal oxide material layer to form the first metal oxide layer 211a, the first oxide layer 212, the second metal oxide layers 213a, the second oxide layer 214, the third metal oxide layers 215a, the third oxide layer 216 and the fourth metal oxide layer 217a.

In this embodiment, the first source/drain feature 222 and the second source/drain feature 224 are disposed in the first opening O1 and the second opening O2 and extending into the semiconductor structure 210. In some embodiments, the first source/drain feature 222 and the second source/drain feature 224 are penetrating through the third oxide layer 216 and the fourth metal oxide semiconductor 217. The first source/drain feature 222 and the second source/drain feature 224 are directly in contact with the third metal oxide semiconductor 215, the third oxide layer 216 and the fourth metal oxide semiconductor 217.

In some embodiments, each of the first oxide layer 212, the second oxide layer 214 and the third oxide layer 216 is a continuous film, a porous film or a discontinuous film, but the disclosure is not limited thereto. In other embodiments, the first oxide layer 212 includes a plurality of particles dispersed on the interface between the first metal oxide semiconductor 211 and the second metal oxide semiconductor 213, the second oxide layer 214 includes a plurality of particles dispersed on the interface between the second metal oxide semiconductor 213 and the third metal oxide semiconductor 215, and the third oxide layer 216 includes a plurality of particles dispersed on the interface between the third metal oxide semiconductor 215 and the fourth metal oxide semiconductor 217.

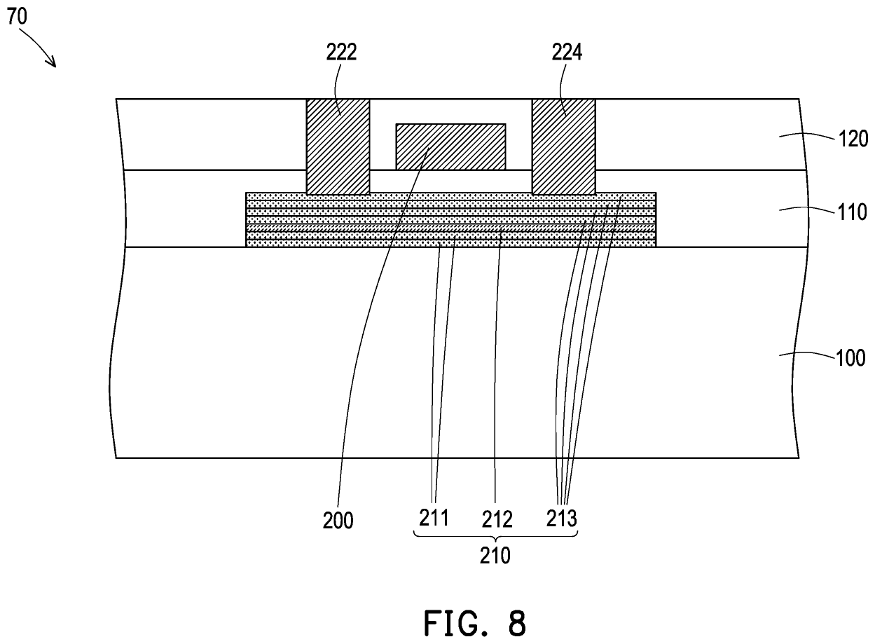

FIG. 8 is a schematic cross-sectional view of a semiconductor device 70 in accordance with some embodiments of the disclosure. It should be noted herein that, in embodiments provided in FIG. 8, element numerals and partial content of the embodiments provided in FIG. 4 are followed, the same or similar reference numerals being used to represent the same or similar elements, and description of the same technical content being omitted. For a description of an omitted part, reference may be made to the foregoing embodiment, and the descriptions thereof are omitted herein.

The difference between the semiconductor device 70 in FIG. 8 and the semiconductor device 30 in FIG. 4 is that: the gate 200 is located under the semiconductor structure 210 in the semiconductor device 30, and the gate 200 is located above the semiconductor structure 210 in the semiconductor device 70. In the semiconductor device 70, the gate 200 is disposed between the gate insulating layer 110 and the interlayer dielectric layer 120.

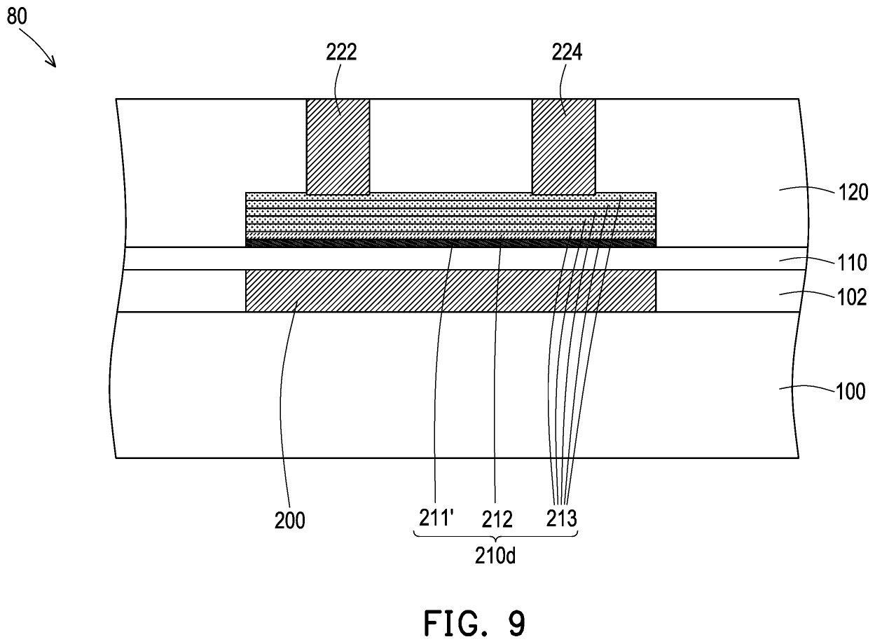

FIG. 9 is a schematic cross-sectional view of a semiconductor device 80 in accordance with some embodiments of the disclosure. It should be noted herein that, in embodiments provided in FIG. 9, element numerals and partial content of the embodiments provided in FIG. 4 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 9, the semiconductor structure 210d includes a first metal oxide layer 211′, a first oxide layer 212 and second metal oxide layers 213. The first oxide layer 212 is located between the first metal oxide layer 211′ and the second metal oxide layers 213. In this embodiment, some atoms of the first oxide layer 212, such as Si, W, Zr, Hf or Al, may diffuse into the first metal oxide layer 211′ during the formation of the semiconductor structure 210d.

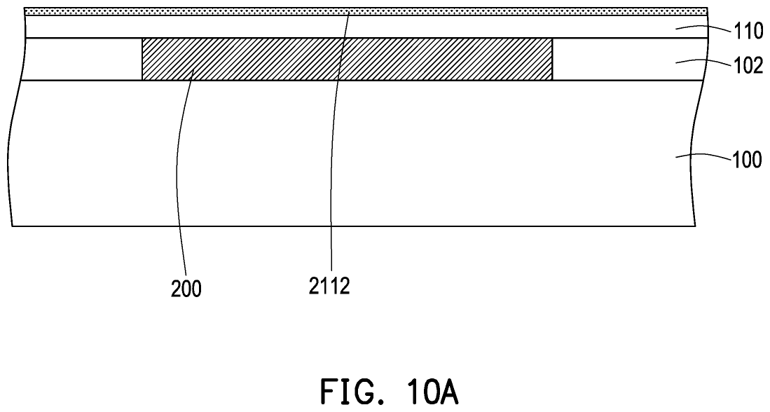

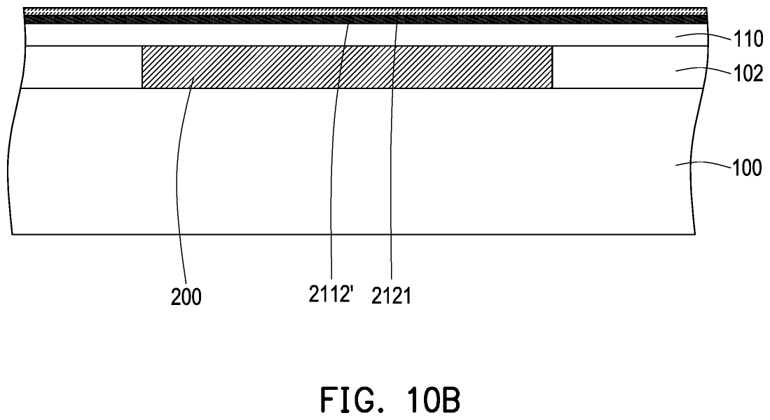

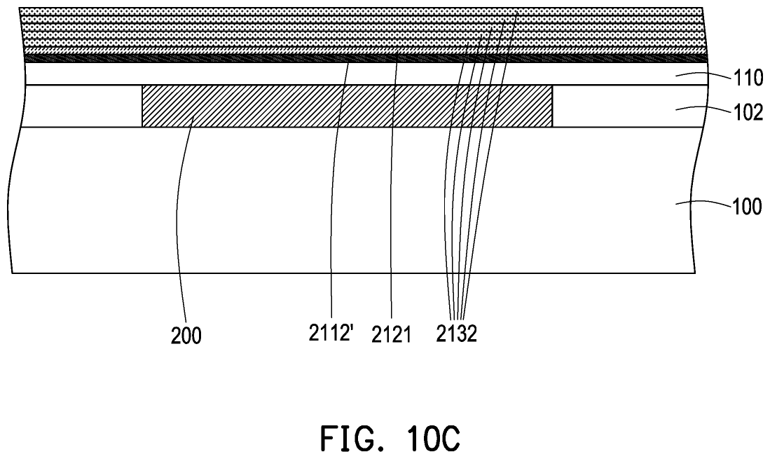

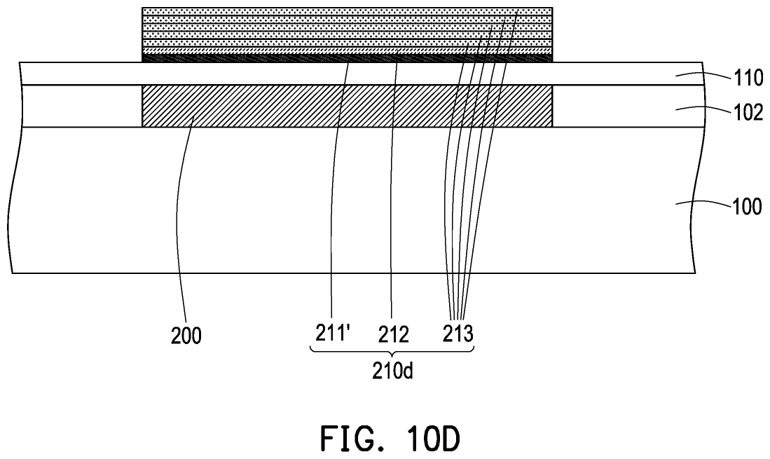

FIG. 10A to FIG. 10D are schematic cross-sectional views of various stages in a fabrication method of a semiconductor device 80 in accordance with some embodiments of the disclosure. Referring to FIG. 10A, one or more first metal oxide material layer 2112 is formed, by ALD, PVD, or the like, above the gate insulating layer 110. In some embodiments, the at least one first metal oxide material layer 2112 may be selected from at least one of the followings: an indium oxide layer, a zinc oxide layer, a tungsten oxide layer and a gallium oxide layer.

Referring to FIG. 10B, a first oxide material layer 2121 is formed above the first metal oxide material layer 2112 by applying a gas to an exposed surface of the at least one first metal oxide material layer 2112, wherein the gas includes SiH₄, WF₆, ZrCl₄, HfCl₄ or Al(CH)₃. In the process of forming the first oxide material layer 2121, part of the gas will penetrate into the first metal oxide material layer 2112, causing some elements in the gas to react with the first metal oxide material layer 2112, resulting in a formation of the first metal oxide material layer 2112′.

Referring to FIG. 10C, second metal oxide material layers 2132 are formed, by ALD, PVD, or the like, above the first oxide material layer 2121. In some embodiments, the second metal oxide material layers 2132 may be selected from at least one of the followings: an indium oxide layer, a zinc oxide layer, a tungsten oxide layer and a gallium oxide layer.

Referring to FIG. 10D, one or more etching process is performed to pattern the first metal oxide material layer 2112′, the first oxide material layer 2121 and the second metal oxide material layers 2132 to form the first metal oxide layer 211′, the first oxide layer 212 and the second metal oxide layers 213. In some embodiments, one or more first metal oxide layer 211′ may be refer as a first metal oxide semiconductor. In some embodiments, the second metal oxide layers 213 may be refer as a second metal oxide semiconductor.

Then, referring to FIG. 9, the interlayer dielectric layer 120, the first source/drain feature 222 and the second source/drain feature 224 are formed.

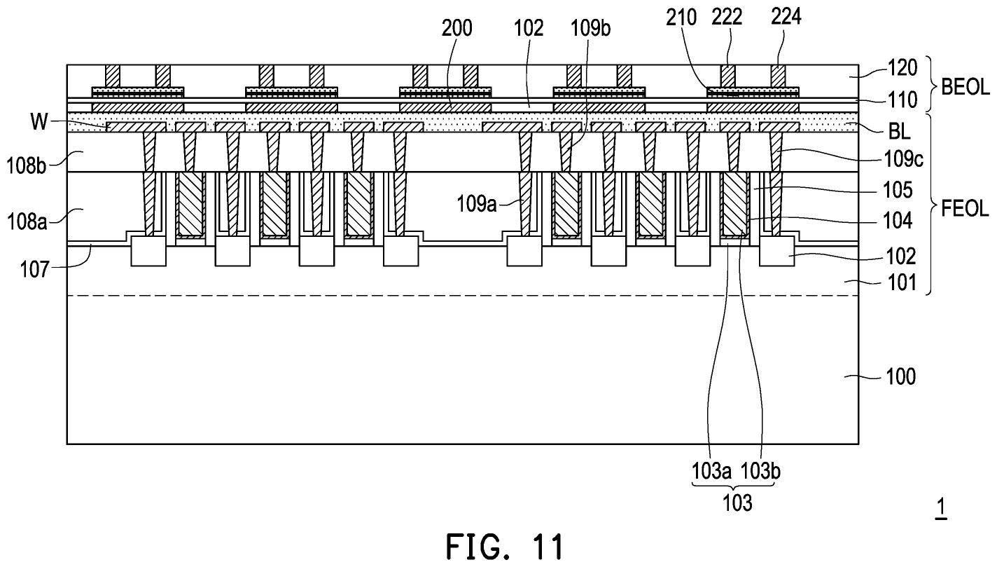

FIG. 11 is a schematic cross-sectional view of an integrated circuit device 1 in accordance with some embodiments of the disclosure.

As shown in FIG. 11, the integrated circuit device 1 includes front end of line (FEOL) devices formed on the substrate 100 and back end of line (BEOL) devices formed above the FEOL devices. In some embodiment, the FEOL devices include MOS-FETs, Fin-FETs, NCFETs or other applicable transistors. The BEOL devices include semiconductor device of any of the foregoing embodiments.

Referring to FIG. 11, multiple fin structures 101 are formed on the substrate 100. Epitaxial structures 102 are respectively formed over the fin structures 101, in accordance with some embodiments. The epitaxial structures 102 may function as source/drain features. Gate stacks 103 are disposed over the fin structures 101. Each of the gate stacks 103 includes a dielectric layer 103a and a gate electrode 103b. Ferroelectric layers 104 are disposed between the dielectric layers 103a and the gate electrodes 103b. Spacer elements 105 are disposed by the sidewall portions of the ferroelectric layers 104 and the gate stacks 103. An etch stop layer 107 is disposed on the epitaxial structures 102 and the spacer elements 105. A dielectric layer 108a is disposed on the etch stop layer 107. The contacts 109a are formed to penetrated through the dielectric layer 108a and the etch stop layer 107, and the contacts 109a may serve as bottom portions of source/drain feature contacts which are electrically connected to the epitaxial structures 102 (i.e. the source/drain features 102).

The dielectric layer 108b may be deposited over the dielectric layer 108a. The contacts 109b and 109c are formed to penetrated through the dielectric layer 108b, the contact 109b may serve as gate contacts which are electrically connected to the gate electrode 103b, and the contacts 109c land on the contacts 109a and may serve as upper portions of source/drain feature contacts.

The conductive wirings W may be formed on the dielectric layer 108b to electrically connected to the contacts 109b and 109c. A buffer layer BL is formed over the dielectric layer 108b to cover the conductive wirings W. In some embodiments, the buffer layer BL may serve as a diffusion barrier layer for preventing contamination resulted from manufacturing processes of back end of line.

After forming the buffer layer BL, the BEOL devices including semiconductor devices are formed on the buffer layer BL. The fabrication method of the semiconductor devices of the BEOL devices can be referred to any of the foregoing embodiments. In this embodiment, the semiconductor devices include gates 200, semiconductor structures 210, a gate insulating layer 110, first source/drain features 222, second source/drain features 224, an insulator 102 and an interlayer dielectric layer 120.

In accordance with one aspect of the present disclosure, a semiconductor device includes a gate, a semiconductor structure, a gate insulating layer, a first source/drain feature and a second source/drain feature. The gate insulating layer is located between the gate and the semiconductor structure. The semiconductor structure includes at least one first metal oxide layer, a first oxide layer, and at least one second metal oxide layer. The first oxide layer is located between the first metal oxide layer and the second metal oxide layer. The first source/drain feature and the second source/drain feature are electrically connected with the semiconductor structure.

In accordance with another aspect of the present disclosure, a semiconductor device includes a gate, a semiconductor structure, a gate insulating layer, a first source/drain feature and a second source/drain feature. The gate insulating layer is located between the gate and the semiconductor structure. The semiconductor structure includes a first metal oxide semiconductor, a first oxide layer, and a second metal oxide semiconductor. The first oxide layer is located between the first metal oxide semiconductor and the second metal oxide semiconductor. Oxygen in the first oxide layer is more stable than oxygen in the first metal oxide semiconductor and oxygen in the second metal oxide semiconductor. The first source/drain feature and the second source/drain feature are electrically connected with the semiconductor structure.

In accordance with another aspect of the present disclosure, a fabricating method of a semiconductor device includes the following steps. A gate, a semiconductor structure and a gate insulating layer located between the gate and the semiconductor structure are formed. A first source/drain feature and a second source/drain feature electrically connected with the semiconductor structure are formed. A method of forming the semiconductor structure includes the following steps. At least one first metal oxide material layer is formed. A first oxide material layer is formed above the at least one first metal oxide material layer. At least one second metal oxide material layer is formed above the first oxide material layer. One or more etching process is performed to pattern the at least one first metal oxide material layer, the first oxide material layer and the at least one second metal oxide material layer to form at least one first metal oxide layer, a first oxide layer and at least one second metal oxide layer, wherein the first oxide layer is located between the at least one first metal oxide layer and the at least one second metal oxide layer.

The foregoing outlines features of several embodiments so that those skilled in the art may better understand the aspects of the present disclosure. Those skilled in the art should appreciate that they may readily use the present disclosure as a basis for de signing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a gate, a semiconductor structure and a gate insulating layer located between the gate and the semiconductor structure, wherein the semiconductor structure comprises:
at least one first metal oxide layer;
a first oxide layer; and
at least one second metal oxide layer, wherein the first oxide layer is located between the at least one first metal oxide layer and the at least one second metal oxide layer; and
a first source/drain feature and a second source/drain feature, electrically connected with the semiconductor structure.

2. The semiconductor device of claim 1, wherein a material of the first oxide layer comprises hafnium oxide, zirconium oxide, lanthanum oxide, silicon oxide, aluminium oxide, gallium oxide or tungsten oxide.

3. The semiconductor device of claim 1, wherein an average bond energy between oxygen and other ions in the first oxide layer is greater than an average bond energy between oxygen and other ions in the at least one first metal oxide layer and an average bond energy between oxygen and other ions in the at least one second metal oxide layer.

4. The semiconductor device of claim 1, wherein the semiconductor structure further comprises:
a second oxide layer; and
at least one third metal oxide layer, wherein the second oxide layer is located between the at least one second metal oxide layer and the at least one third metal oxide layer, wherein oxygen in the second oxide layer is more stable than oxygen in the at least one second metal oxide layer and oxygen in the at least one third metal oxide layer.

5. The semiconductor device of claim 4, wherein the semiconductor structure further comprises:
a third oxide layer; and
at least one fourth metal oxide layer, wherein the third oxide layer is located between the at least one third metal oxide layer and the at least one fourth metal oxide layer, wherein oxygen in the third oxide layer is more stable than oxygen in the at least one third metal oxide layer and oxygen in the at least one fourth metal oxide layer.

6. The semiconductor device of claim 1, wherein the first source/drain feature and the second source/drain feature are extending into the semiconductor structure.

7. The semiconductor device of claim 1, wherein a width of the first oxide layer is substantially equal to a width of the at least one first metal oxide layer and a width of the at least one second metal oxide layer.

8. The semiconductor device of claim 1, wherein the first oxide layer is a continuous film, a porous film or a discontinuous film.

9. A semiconductor device, comprising:
a gate, a semiconductor structure and a gate insulating layer located between the gate and the semiconductor structure, wherein the semiconductor structure comprises:
a first metal oxide semiconductor;
a first oxide layer; and
a second metal oxide semiconductor, wherein the first oxide layer is located between the first metal oxide semiconductor and the second metal oxide semiconductor, and oxygen in the first oxide layer is more stable than oxygen in the first metal oxide semiconductor and oxygen in the second metal oxide semiconductor; and
a first source/drain feature and a second source/drain feature, electrically connected with the semiconductor structure.

10. The semiconductor device of claim 9, wherein materials of the first metal oxide semiconductor and a material of the second metal oxide semiconductor comprise at least one of indium zinc oxide, indium gallium oxide, indium gallium zinc oxide, indium tungsten oxide or indium tungsten zinc oxide.

11. The semiconductor device of claim 9, wherein the semiconductor structure further comprises:
a second oxide layer; and
a third metal oxide semiconductor, wherein the second oxide layer is located between the second metal oxide semiconductor and the third metal oxide semiconductor, wherein an average bond energy between oxygen and other ions in the second oxide layer is greater than an average bond energy between oxygen and other ions in the second metal oxide semiconductor and an average bond energy between oxygen and other ions in the third metal oxide semiconductor.

12. The semiconductor device of claim 11, wherein the first source/drain feature and the second source/drain feature are penetrating through the second oxide layer.

13. The semiconductor device of claim 9, wherein A is an atom other than oxygen in the first oxide layer, and B is an atom other than oxygen in the first metal oxide semiconductor and the second metal oxide semiconductor, wherein the dissociation energy of A-O is larger than the dissociation energy of B-O.

14. The semiconductor device of claim 9, wherein the first oxide layer comprises a plurality of particles dispersed on an interface between the first metal oxide semiconductor and the second metal oxide semiconductor.

15. A fabricating method of a semiconductor device, comprising:
forming a gate, a semiconductor structure and a gate insulating layer located between the gate and the semiconductor structure, wherein a method of forming the semiconductor structure comprises:
forming at least one first metal oxide material layer;
forming a first oxide material layer above the at least one first metal oxide material layer; and
forming at least one second metal oxide material layer above the first oxide material layer; and
performing one or more etching process to pattern the at least one first metal oxide material layer, the first oxide material layer and the at least one second metal oxide material layer to form at least one first metal oxide layer, a first oxide layer and at least one second metal oxide layer, wherein the first oxide layer is located between the at least one first metal oxide layer and the at least one second metal oxide layer; and
forming a first source/drain feature and a second source/drain feature electrically connected with the semiconductor structure.

16. The fabricating method of claim 15, wherein the bond energy of oxygen in the first oxide layer is larger than the bond energy of oxygen in the at least one first metal oxide layer and the bond energy of oxygen in the at least one second metal oxide layer.

17. The fabricating method of claim 15, wherein the method of forming the semiconductor structure further comprises:
forming a second oxide material layer above the at least one second metal oxide material layer; and
forming at least one third metal oxide material layer above the second oxide material layer; and
performing the one or more etching process to pattern the second oxide material layer and the at least one third metal oxide material layer to form a second oxide layer and at least one third metal oxide layer.

18. The fabricating method of claim 15, further comprising:
forming an interlayer dielectric layer above the semiconductor structure;
performing a removal process to forming a first opening and a second opening in the interlayer dielectric layer, wherein the first opening and the second opening are extending into the semiconductor structure; and
forming the first source/drain feature and the second source/drain feature in the first opening and the second opening, respectively.

19. The fabricating method of claim 15, wherein the first oxide layer is a continuous film, a porous film or a discontinuous film.

20. The fabricating method of claim 15, wherein a method of forming the first oxide material layer comprises:
applying a gas to an exposed surface of the at least one first metal oxide material layer, wherein the gas comprises SiH₄, WF₆, ZrCl₄, HfCl₄ or Al(CH)₃.
